(19) United States
(12) Patent Application Publication
(10) Pub. No.: US 2007/0184179 A1
(43) Pub. Date: Aug. 9, 2007

(54) Methods and apparatus to monitor a process of depositing a constituent of a multi-constituent gas during production of a composite brake disc

(76) Inventors: Akshay Waghray, Granger, IN (US); David E. Parker, Granger, IN (US); Douglas J. Steinke, South Bend, IN (US); David W. Linville, Atlanta, GA (US)

Correspondence Address: HANLEY, FLIGHT & ZIMMERMAN, LLC, 150 S. WACKER DRIVE, SUITE 2100, CHICAGO, IL, 60606, US

(21) Appl. No.: 11/350,686

(22) Filed: Feb. 9, 2006

(51) Int. Cl. C23C 16/52; B05C 11/00

(52) U.S. Cl. 427/8; 118/679

(57) ABSTRACT

Methods and apparatus to monitor a process of depositing a constituent of a multi-constituent gas are disclosed. The methods and apparatus may be used in a process for producing a carbon-carbon composite brake disc.

### FIELD OF THE DISCLOSURE

This disclosure relates generally to methods and apparatus to monitor a process of depositing a constituent of a multi-constituent gas during production of a composite brake disc and, more particularly, to methods and apparatus to monitor a process for producing a carbon-carbon composite brake disc.

### BACKGROUND

The use of carbon-carbon composite brake discs in aircraft brakes, which have been referred to as carbon brakes, is well known in the aerospace industry. The use of carbon-carbon composite brake discs is attractive because the carbon-carbon composite material is lightweight, can operate at very high temperatures, and can absorb a large amount of aircraft braking torque and convert it to heat.

Typically, carbon-carbon composite brake discs are manufactured by placing porous brake disc preforms in a furnace such as a chemical vapor deposition (CVD) or chemical vapor infiltration (CVI) furnace or reactor, and transmitting hydrocarbon gases, for example, natural gas, through the reactor at a high temperature to effect the deposition of pyrocarbon on the porous brake disc preforms. Usually, several cycles of depositing pyrocarbon on the porous brake disc preforms in the reactor are required to attain the required density for the carbon-carbon brake discs. The time required for each infiltration or deposition cycle to reach the maximum brake disc density attainable during the cycle depends on numerous factors such as, for example, the initial density of the brake disc preform and the loading factor for the reactor. Currently, CVD/CVI cycles of fixed time duration are utilized for such processes. However, a reactor can be used more efficiently if it is possible to determine the point at which the weight gain and thus the density, of the brake disc preform reaches its maximum or limiting value during the reactor cycle. The determination of the time at which the density of the brake disc preform has reached its limiting value during the reactor cycle, and therefore the determination of the time at which the reactor cycle is to be terminated, can result in significant cost savings in natural gas and electricity usage, and may also shorten reactor cycle times whereby the reactor could be used for more densification cycles.

### BRIEF DESCRIPTION OF THE DRAWINGS

FIG. 1 is an example representation of a CVD or CVI furnace utilizing the example methods and apparatus described herein to monitor a process of depositing a constituent of a multi-constituent gas.

FIG. 2 is an example chart illustrating the change in the density of a porous part in relation to the time that a reactor is operating to deposit a constituent of a multi-constituent gas, and the change in the density of the porous part in relation to the changes in concentrations of two remaining constituents of the multi-constituent gas during the operation of the reactor of FIG. 1.

FIG. 3 is a representative flow diagram of an example method that may be used to monitor a process of depositing a constituent of a multi-constituent gas during the production of a composite brake disc.

### DETAILED DESCRIPTION

In general, the example methods and apparatus to monitor a process of depositing a constituent of a multi-constituent gas may be used to manufacture brake discs from various materials and by various deposition methods, and any combinations thereof.

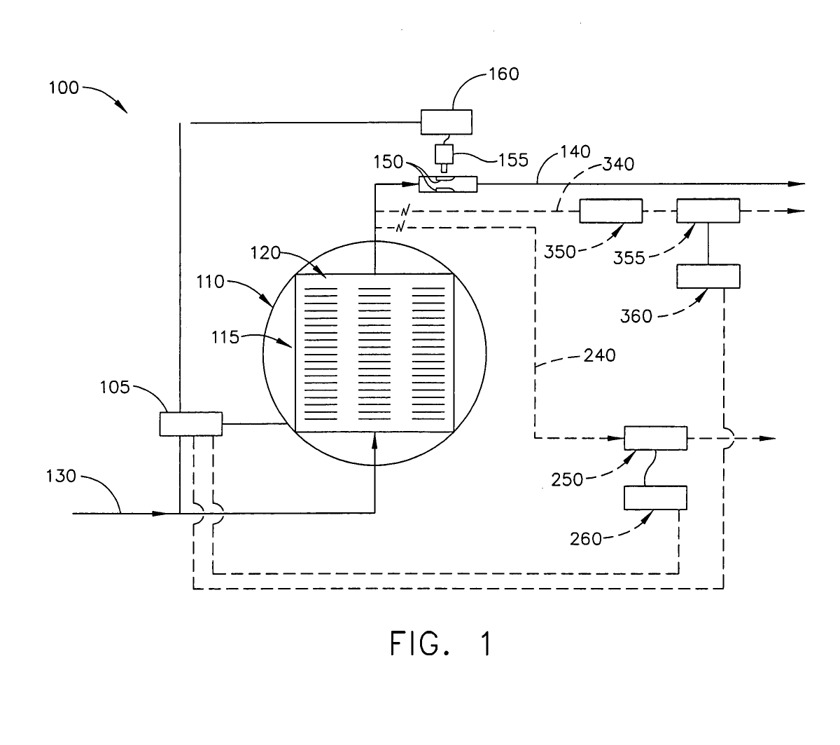

FIG. 1 is an example apparatus 100 including a CVD or CVI furnace or reactor 110 utilizing the example methods and apparatus to monitor a process of depositing a constituent of a multi-constituent gas. In particular, the example apparatus utilizes the example methods and apparatus described herein in the manufacture of a carbon-carbon composite brake disc. In FIG. 1, the example apparatus 100 includes the reactor 110, which receives hydrocarbon gases by way of an inlet line 130 and emits the hydrocarbon gases by way of an outlet line 140. The outlet line 140 communicates with a vacuum pump or similar device (not shown) to achieve the emission of the hydrocarbon gases from the reactor 110 through the outlet line 140. A control mechanism 105 communicates with and controls the operation of the reactor 110 and the vacuum pump to control the flow of gases through the inlet line 130. The control mechanism 105 can terminate both the flow of gases in the inlet line 130 and the operation of the reactor 110. As is well known to those skilled in the art, the reactor 110 includes a retort 115 within which are located a plurality of stacks of porous material or porous parts 120. Typically, the porous parts 120 are carbon fiber preforms which will be densified during one or more reactor cycles of the densification process to produce carbon-carbon composite brake discs. As is well known in the art, the preforms or porous parts 120 may be any of numerous types of preforms, for example, random fiber, nonwoven fiber, or resin impregnated layers. Additionally, the porous parts 120 may be previously densified at least partially by any of numerous densification processes such as, for example, CVD or CVI, liquid phase densification processes such as hot isostatic pressing (HIP), pressurized impregnation carbonization (PIC), vacuum pressure infiltration (VPI), pitch or resin injection, or combinations of these densification processes.

In the example representation of FIG. 1, the inlet line 130 provides hydrocarbon gases and other gases utilized in the reactor 110 to achieve the densification of the porous parts 120. Persons of ordinary skill in the art know that the gases may include initially an inert gas such as argon or nitrogen while the reactor 110 reaches a desired high temperature. After the reactor 110 has reached a desired high temperature, the inert gas may be replaced by the hydrocarbon gases or primary carbon-bearing gases such as methane, natural gas, ethane, propane, butane, propylene, acetylene, or combinations of these gases. The primary carbon-bearing gases are a multi-constituent gas transmitted through the inlet line 130 to the reactor 110, which is maintained at a high temperature during the densification process. The high temperature within the reactor 110 causes the multi-constituent gas to decompose and deposit carbon into the porous parts 120 during the densification process, and the remaining constituents of the multi-constituent gas including hydrogen are transmitted to the outlet line 140. It should be clearly understood that the deposition of carbon into the porous parts 120 includes the deposition of carbon into, throughout, and onto the porous parts 120, thereby achieving an increase in the weight and density of each of the porous parts 120. As is well known by those skilled in the art, a densification process and related equipment may include a wide variety of cycle times, temperatures, porous parts, number of parts, furnaces or reactors, gases for densification, and accessory or auxiliary equipment such as, for example, controls, pumps, sensors, etc.

In the example representation in FIG. 1, the outlet line 140 of the apparatus 100 includes optical windows 150 for a near-infrared spectrometer (NIRS) device 155 having a source and detector (not shown) to measure the concentrations of certain species or constituents of the multi-constituent gas exhausted through outlet line 140. The NIRS device 155 has the capability to distinguish between various constituents of the multi-constituent gas such as, for example, methane, ethane, propane, etc., to determine an absolute or relative partial pressure of each of the constituent gases, e.g. concentrations, within the multi-constituent gas. As will be disclosed below, changes in the concentrations of certain constituent gases correspond closely to the change in the density of the porous parts 120 during the densification process.

The NIRS device 155 communicates with a computer or processing unit 160. The data related to the concentrations of one or more constituents of the multi-constituent gas in the outlet line 140 is communicated from the NIRS device 155 to the processing unit 160, which analyzes, in real time, the data and changes in the concentrations of the constituents of the multi-constituent gas.

As is well known to those in the chemical, agricultural, food and pharmaceutical industries, near-infrared spectroscopy has been used for on-line and in-line measurements during production. For example, the use of near-infrared spectroscopy has enabled the pharmaceutical industry to implement real time analysis and control in various stages of manufacturing of pharmaceutical products. Near-infrared spectroscopy is adaptable to reflectance, transflectance or transmission type measurements and, thus provides numerous sampling options for solids, liquids or gases. Coupled with the immense computing power provided by the rapid advance in computers, near-infrared spectroscopy data can be instantaneously analyzed in real time to extract information (e.g., concentration) for more than one constituent of a multi-constituent gas. Numerous types of near-infrared spectrometers such as, for example, moving grating-scanning monochrometor, acoustic-optic tunable filter, Fourier transform near-infrared, filer photometer, and fixed grating-diode array, are available. Near-infrared spectrometers and related equipment may be obtained from or through numerous companies such as, for example, Control Development, Inc. of South Bend, Indiana.

The example representation of FIG. 1 also includes the alternative use of an on-line quadrupole mass spectrometer (QMS) device 250 in a slipstream outlet line 240, which communicates with a differential vacuum pump (not shown). This alternative use of the QMS device 250 requires the use of the slipstream output line 240 and the differential vacuum pump because the QMS device 250 operates at significantly lower pressures. The QMS device 250 communicates with a computer or processing unit 260. The QMS device 250 can detect certain constituents of the multi-constituent gas exhausted through the slipstream outlet line 240. Data related to the concentrations of one or more constituents of the multi-constituent gas in the outlet line 240 are communicated from the QMS device 250 to the processing unit 260, which analyzes, in real time, the data and changes in the concentrations of the constituents of the multi-constituent gas. It should be clearly understood that either the NIRS device 155 or the QMS device 250 can be used in the example methods and apparatus disclosed herein.

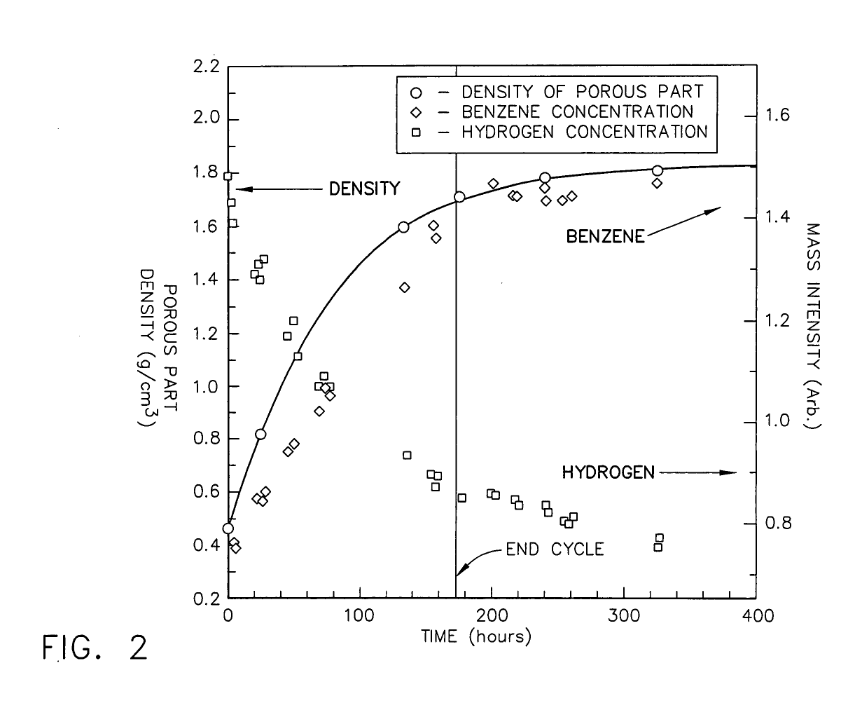

As can be seen in FIG. 2, the change in the density of a porous part (e.g., one of the porous parts 120) over a period of time is related to the absolute or relative partial pressures (e.g., concentrations) of certain constituents of the multi-constituent gas exiting a reactor (e.g. the reactor 110). The use of a mass spectrometer to monitor the exhaust gas of a subscale reactor (not shown) has established that the concentrations of certain constituents such as, for example, aromatics, provide indications of the change in weight, and thus the change in density of the porous part in the subscale reactor.

More specifically, the mass spectrometer measured the atomic mass intensity (e.g. concentration) of the constituent gases benzene and hydrogen in the multi-constituent gas exiting the subscale reactor, and the mass intensity data was assembled as normalized units expressed as arbitrary units. In the example chart of FIG. 2, the density of the porous part in grams per cubic centimeter is represented on the left vertical axis of the chart, the time of the densification cycle in hundreds of hours is represented on the horizontal axis of the chart, and the atomic mass intensity in arbitrary units of the benzene and hydrogen constituents of the multi-constituent gas exiting the subscale reactor is represented on right vertical axis of the chart.

As can be seen in FIG. 2, as the density of the porous part approaches 1.8 gm/cm³, the concentration of an aromatic (i.e., benzene) changes rapidly during approximately the first 200 hours of the densification process. However, the concentration of benzene in the multi-constituent gas begins to level off or approach a limiting value of about 1.5 arbitrary units as the density of the porous part reaches its limiting or maximum value of 1.8 gm/cm³ during the densification process cycle. Aromatics such as, for example, benzene and toluene, have been found to correspond to the changes in density of the porous parts during the densification cycle. However, other constituents may also be utilized in the example methods and apparatus. For example, the concentration of acetylene may be tracked for a densification process of porous parts made from polyacrylonitrile (PAN) oxidized fibers.

As can be readily seen in FIG. 2, the density of the porous part reaches a limiting density of about 1.7 gm/cm³ (highlighted generally by the density arrow) when the concentration of benzene reaches a limiting value of about 1.44 arbitrary units (highlighted generally by the benzene arrow). The limiting density of about 1.7 gm/cm³ and limiting value of about 1.44 arbitrary units corresponds to a cycle time of approximately 170 hours. Thus, the densification cycle could advantageously be terminated or ended at about 170 hours, instead of continuing the densification cycle for a fixed time of as long as 400 hours as was the case in some known processing methods.

As illustrated in example chart FIG. 2, the concentration of hydrogen can also be utilized in the example methods and apparatus. As the density of the porous part increases during the densification process cycle, the concentration of the hydrogen constituent of the multi-constituent gas decreases and reaches a value of about 0.9 arbitrary units when the density of the porous part is about 1.7 g/cm³. The density of about 1.7 gm/cm³ and the value of about 0.9 arbitrary units also corresponds to the densification process cycle time of about 170 hours and, thus, the concentration of hydrogen can be used as an indicator of the density of the porous part.

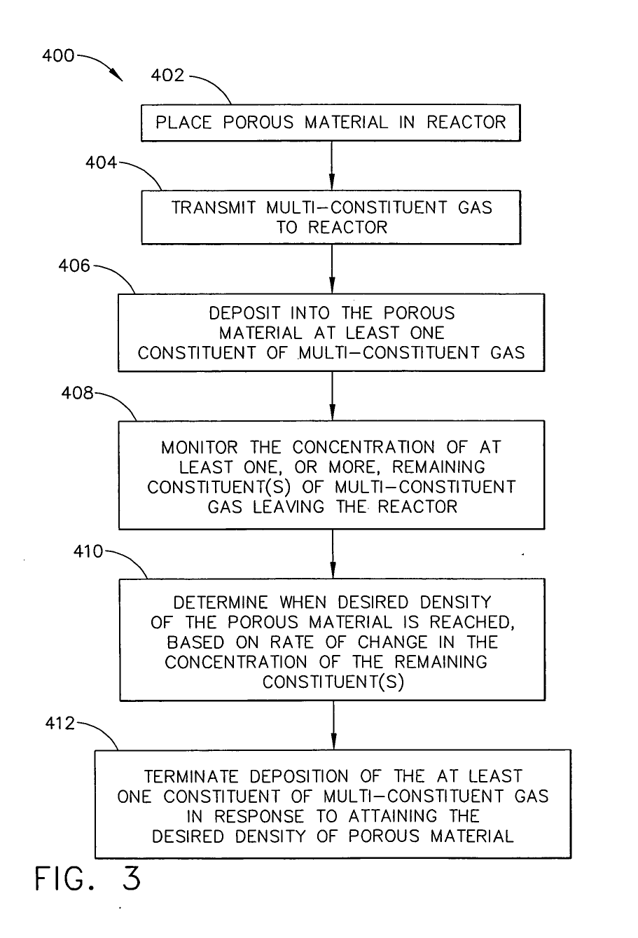

FIG. 3 is a representative flow diagram of an example method 300 that may be used to monitor a process of depositing a constituent of a multi-constituent gas during the production of a composite brake disc and, more particularly, the production of a carbon-carbon composite brake disc. Initially, a porous material (e.g., a preform or preforms such as the porous parts 120 in FIG. 1) is placed (block 302) in a reactor (e.g., the reactor 110). Hydrocarbon gases or primary carbon-bearing gases such as methane, natural gas, ethane, propane, butane, propylene, acetylene, or combinations of these gases, constitute a multi-constituent gas transmitted to the reactor (block 304). The temperature in the reactor, which is maintained at a high temperature during the densification process, causes the multi-constituent gas to decompose and deposit at least one constituent of the multi-constituent gas (block 306) such as, for example, carbon into the porous material during the densification process. The remaining constituents of the multi-constituent gas are transmitted from or leave the reactor and the concentration of at least one, or more, remaining constituent or constituents of the multi-constituent gas is monitored (block 308). This can be accomplished by equipment such as, for example, a near infrared spectrometer (e.g., the NIRS device 155) or a quadrupole mass spectrometer (e.g., the QMS device 250). The method 300 includes an analysis of the rate of change in the concentration of at least one, or more, remaining constituent(s) of the multi-constituent gas, to determine when a desired density (e.g., the porous part density in FIG. 2) of the porous material is reached (block 310). As disclosed in FIG. 2, the change in the density of the porous material (e.g., one of the porous parts 120) over a period of time is related to the concentrations of certain constituents (e.g., benzene or hydrogen in FIG. 2) of the multi-constituent gas exiting the reactor. The analysis can be accomplished by equipment such as, for example, a computer or processing unit (e.g., the computers or processing units 160 and 260). Finally, the deposition of the at least one constituent of the multi-constituent gas is terminated in response to attaining the desired density of the porous material (block 312). A control mechanism (e.g., the control mechanism 105), which communicates with the reactor, processing unit, and other ancillary equipment such as, for example, a vacuum pump, may be utilized to terminate the deposition of at least one constituent of the multi-constituent gas.

As can be seen from FIG. 2 and the example method 300 in FIG. 3, the use of the on-line or in-line NIR device 155 and/or QMS device 250 can achieve significant savings in the use of natural gas and electricity by way of shortened densification cycle times. Additionally, the example apparatus and methods described herein can achieve an increase in reactor time available for the processing of additional porous parts, thereby reducing the cost of parts. The example methods and apparatus of this disclosure additionally provide for real time, on-line or in-line process control, direct and non-invasive monitoring, improved process control, and improved response times for customer demands for products.

The example methods and apparatus is described with reference to the illustrations of FIGS. 1, 2 and 3, and persons of ordinary skill in the art will readily appreciate that other methods of implementing the example methods may alternatively be used. For example, the types of porous parts and densification processes may be changed, and/or some of the parts and processes described may be changed, eliminated, or combined.

Although certain example methods and apparatus have been described herein, the scope of coverage of this patent is not limited thereto. On the contrary, this patent covers all methods, apparatus and articles of manufacture fairly falling within the scope of the appended claims either literally or under the doctrine of equivalents.

What is claimed is:

1. A method to monitor a process of depositing a constituent of a multi-constituent gas, the method comprising:
placing a porous material in a reactor having an outlet;
transmitting a multi-constituent gas to the reactor, wherein at least one constituent of the multi-constituent gas is deposited on the porous material to increase the density of the porous material;
monitoring, during the deposition of the at least one constituent, the multi-constituent gas in the outlet of the reactor to determine periodically the concentration of at least one remaining constituent of the multi-constituent gas;
determining, without removing the material from the reactor, when the material has attained a desired density based on a rate of change in the concentration of the at least one remaining constituent; and
terminating the process of depositing the at least one constituent of the multi-constituent gas in response to determining the material has attained the desired density.

2. A method as defined in claim 1, wherein the material of desired density is used as a composite friction material.

3. A method as defined in claim 1, wherein the reactor is a chemical vapor deposition furnace.

4. A method as defined in claim 1, wherein the remaining constituent is an aromatic compound.

5. A method as defined in claim 4, wherein the aromatic compound comprises at least one of benzene, toluene, or acetylene.

6. A method as defined in claim 1, wherein the remaining constituent is hydrogen.

7. A method as defined in claim 1, wherein the monitoring comprises using a near-infrared spectrometer to determine the concentration of the at least one remaining constituent.

8. A method as defined in claim 1, wherein the monitoring comprises using a mass spectrometer to determine the concentration of the at least one remaining constituent.

9. A method to as defined in claim 1, wherein the monitoring further comprises determining the concentrations of multiple constituents remaining in the multi-constituent gas.

10. A method as defined in claim 9, wherein the concentrations comprise the partial pressures of the multiple constituents remaining in the multi-constituent gas.

11. Apparatus to monitor a process of depositing a constituent of a multi-constituent gas, comprising:
a reactor having an inlet and an outlet, wherein the reactor is configured to deposit at least one constituent of a multi-constituent gas on a porous material within the reactor;
a monitor to determine during the deposition of the at least one constituent the concentration of at least one remaining constituent of the multi-constituent gas; and
a processing unit coupled to the monitor and configured to determine, without removing the material from the reactor, when the material has attained a desired density based on a rate of change in the concentration of the at least one remaining constituent.

12. An apparatus as defined in claim 11, wherein the part of desired density is a composite friction material part.

13. An apparatus as defined in claim 11, wherein the reactor is a chemical vapor deposition furnace.

14. An apparatus as defined in claim 1, wherein the remaining constituent is an aromatic compound.

15. An apparatus as defined in claim 14, wherein the aromatic compound comprises at least one of benzene, toluene, or acetylene.

16. An apparatus as defined in claim 11, wherein the remaining constituent is hydrogen.

17. An apparatus as defined in claim 11, wherein the monitoring device comprises a near-infrared spectrometer to determine the concentration of the at least one remaining constituent.

18. An apparatus as defined in claim 11, wherein the monitoring device comprises a mass spectrometer to determine the concentration of the at least one remaining constituent.

19. An apparatus as defined in claim 11, wherein the monitoring device determines the concentrations of multiple constituents remaining in the multi-constituent gas.

20. An apparatus as defined in claim 19, wherein the concentrations comprise the partial pressures of the multiple constituents remaining in the multi-constituent gas.
